(19) United States
(12) Patent Application Publication
(10) Pub. No.: US 2026/0066907 A1
(43) Pub. Date: Mar. 5, 2026

(54) PHASE-LOCKED LOOP WORKING SYSTEM

(71) Applicant: AMICRO SEMICONDUCTOR CO., LTD., Zhuhai (CN)

(72) Inventors: Huaiyu HAN, Zhuhai (CN); Weibing ZHAO, Zhuhai (CN); Yaohua SHAO, Zhuhai (CN)

(73) Assignee: AMICRO SEMICONDUCTOR CO., LTD., Zhuhai (CN)

(21) Appl. No.: 19/385,302

(22) Filed: Nov. 11, 2025

Related U.S. Application Data
(63) Continuation of application No. PCT/CN2024/094131, filed on May 20, 2024.

(30) Foreign Application Priority Data
May 18, 2023 (CN) 202310561245.0

(51) Int. Cl. H03L 7/093; H03L 7/089; H03L 7/099; H03L 7/18

(52) U.S. Cl. CPC H03L 7/093; H03L 7/099; H03L 7/18; H03L 7/0891

(57) ABSTRACT

A phase-locked loop working system includes: a pre-frequency divider, a phase frequency detector, a charge pump, a filter, a voltage-controlled oscillator, a loop frequency divider and a circuit parameter regulator. The phase frequency detector, the charge pump, the filter, the voltage-controlled oscillator and the loop frequency divider are sequentially coupled end to end to form a phase-locked loop circuit. The circuit parameter regulator is coupled to the phase-locked loop circuit and is used to adjust a filtering resistor and a filter capacitor in the filter, to control loop parameters generated by the phase-locked loop circuit to be within a preset margin range. The circuit parameter regulator is coupled to the phase-locked loop circuit and is further used to adjust a frequency-division coefficient of the pre-frequency divider and/or a frequency of the signal to be processed inputted into the pre-frequency divider.

### CROSS-REFERENCE TO RELATED APPLICATIONS

This application is a continuation application of International Application No. PCT/CN2024/094131, filed on May 20, 2024, which claims priority to Chinese Patent Application No. 202310561245.0, filed on May 18, 2023. The disclosures of the above-mentioned applications are hereby incorporated by reference in their entireties.

### TECHNICAL FIELD

This application relates to the field of circuit parameter adjustment technologies of the phase-locked loop, in particular to a phase-locked loop working system.

### BACKGROUND

The phase-locked loop is a very important functional system, such as providing one or more clocks with required frequencies in a chip system, generating local oscillator signals in a receiver, and maintaining synchronization in a communication system. Usually, the phase-locked loop is composed of a phase frequency detector, a charge pump, a low-pass filter, a voltage-controlled oscillator, and a frequency divider, forming a feedback loop. The phase frequency detector is used to detect a frequency difference and phase difference between a feedback signal and a reference signal generated by a crystal oscillator, and generate a pulse control signal. The charge pump, in response to the pulse control signal, provides a charging current or a discharging current for the low-pass filter. The low-pass filter filters the output electrical signal from the charge pump, and inputs the filtered output voltage signal into the voltage-controlled oscillator as a control voltage of the voltage-controlled oscillator. The voltage-controlled oscillator generates an oscillation voltage output signal in response to the control voltage provided by the low-pass filter. The frequency divider is used to perform frequency division on the oscillation voltage output signal and generate a feedback signal inputted to the phase frequency detector. During the operation of the phase-locked loop, when the phases of the reference signal and the feedback signal maintain a fixed difference, it means that the phases of the output voltage and the input voltage are locked, that is, the phase-locked loop is locked. Therefore, an output signal fo with locked frequency and phase is generated through the phase-locked loop circuit.

Kvco, as a gain value of the voltage-controlled oscillator, represents a ratio of a change value of the output frequency of the voltage-controlled oscillator to a change value of its control voltage. When the power supply voltage of the phase-locked loop decreases, the control voltage of the voltage-controlled oscillator also decreases, which means that Kvco needs to increase. The circuit parameter adjustment manner in the prior art may make the change in Kvco smaller, but it reduces a range of the output frequency of the voltage-controlled oscillator, i.e., the margin is lowered, making it difficult for the output frequency of the phase-locked loop to meet the pre-configured frequency accuracy requirements, and potentially causing unstable operation of the phase-locked loop.

For a finalized phase-locked loop circuit, in order to maintain stable loop parameters, when some circuit parameters change significantly, capacitance values of some filtering capacitors need to be increased exponentially, which increases the capacitor area, resulting in an increase in the area occupied by the phase-locked loop circuit to which the capacitor is connected.

### SUMMARY

This application discloses a phase-locked loop working system, and discloses the following technical solution.

The phase-locked loop working system includes: a pre-frequency divider, a phase frequency detector, a charge pump, a filter, a voltage-controlled oscillator, a loop frequency divider and a circuit parameter regulator. The phase frequency detector, the charge pump, the filter, the voltage-controlled oscillator and the loop frequency divider are sequentially coupled end to end to form a phase-locked loop circuit. The circuit parameter regulator is coupled to the phase-locked loop circuit and is used to adjust a filtering resistor and a filter capacitor in the filter, to control loop parameters generated by the phase-locked loop circuit to be within a preset margin range. The circuit parameter regulator is coupled to the phase-locked loop circuit and is further used to adjust a frequency-division coefficient of the pre-frequency divider and/or a frequency of the signal to be processed inputted into the pre-frequency divider, to control the loop parameters generated by the phase-locked loop circuit to be within the preset margin range, and to reduce a capacitance value of the filtering capacitor in the filter. This technical solution achieves precise and flexible control of loop parameters by adjusting the capacitance value and resistance value in the loop filter, and/or by adjusting the frequency division coefficient in the pre-frequency divider, and/or by adjusting the frequency of the signal to be processed inputted into the pre-frequency divider, thereby ensuring stable operation of the phase-locked loop. Furthermore, while maintaining the loop parameters within a certain margin range (which maintains stable operation of the phase-locked loop), it enables the configuration that minimizes the area of the phase-locked loop circuit (including the trend toward smaller filtering capacitors and filtering resistors).

### BRIEF DESCRIPTION OF THE DRAWINGS

FIG. 1 is a block diagram of a phase-locked loop working system according to the embodiments of this application.

FIG. 2 is another block diagram of the phase-locked loop working system according to the embodiments of this application.

### DETAILED DESCRIPTION OF THE EMBODIMENTS

The embodiments of this application will be described in detail below with reference to the accompanying drawings in the embodiments of this application.

Considering that loop parameters of the entire phase-locked loop need to meet certain indicators, such as phase margin, loop bandwidth, and damping coefficient. Generally, decreasing of Kvco mentioned in the Background is achieved by compressing the output frequency range of the voltage-controlled oscillator. For example, the voltage-controlled oscillator originally covered the frequency range of 100 MHz to 200 MHZ, and now it is narrowed to the frequency range of 120 MHz to 180 MHz. In this way, Kvco decreases, but the risk is increased, leading to unstable phase-locked loop operation. Furthermore, generally, to ensure low output frequency and high precision requirements, many parts of the entire loop cannot be adjusted after the overall design. In this regard, the circuit parameters of the filter can only be adjusted to modify the indicators corresponding to the loop parameters. Considering the requirements for the power supply voltage under the corresponding transistor process, Kvco is set larger. In order to meet the corresponding indicator requirements of the loop parameters (make the corresponding indicators in the normal range), it needs to increase the capacitor of the filter, consuming more area, i.e., significantly leading to the increase of a circuit area that actually performs the phase-locked loop function in the circuit system Hence, the large area is the problem faced by the phase-locked loop circuit.

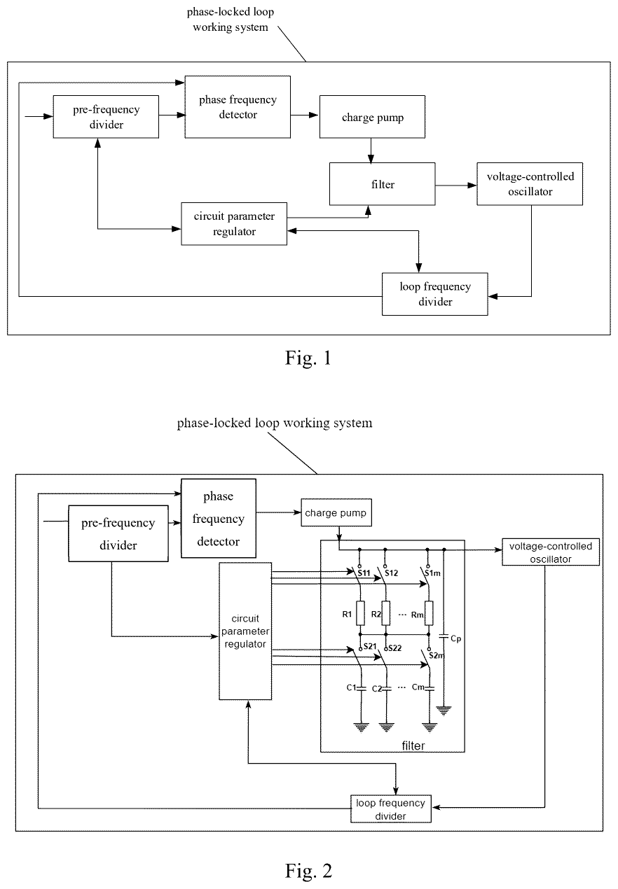

In response to the above-mentioned technical defects, the embodiments of this application disclose a phase-locked loop working system, as shown in FIG. 1, the phase-locked loop working system includes: a pre-frequency divider, a phase frequency detector, a charge pump, a filter, a voltage-controlled oscillator, a loop frequency divider and a circuit parameter regulator. The circuit parameter regulator may be considered as a controller of the phase-locked loop working system, and may be electrically coupled with the pre-frequency divider, the loop frequency divider, the filter and other related circuit modules having a signal triggering or feedback relationship simultaneously. In this embodiment, the frequency division coefficient, resistance value, capacitance value and other circuit parameters are adjusted to control the loop parameters of the phase-locked loop to remain unchanged or within a certain margin. The phase frequency detector, the charge pump, the filter, the voltage-controlled oscillator and the loop frequency divider in this embodiment are sequentially coupled end to end to form a phase-locked loop circuit. Each circuit module forming the phase-locked loop circuit is configured to be connected to a corresponding power source to meet the power supplying requirement. The loop frequency divider corresponds to the frequency divider mentioned in the Background of this application, and is denoted as the loop frequency divider herein, so as to distinguish it from the pre-frequency divider outside the phase-locked loop circuit. Considering the area factor, the filter in this embodiment is configured as a low-pass filter. Alternatively, when only the working stability of the phase-locked loop is considered, the filter in this embodiment may be configured as any other types of filters, which will not be particularly defined herein.

In this embodiment, the circuit parameter regulator is coupled to the phase-locked loop circuit. The circuit parameter regulator is used to control loop parameters generated by the phase-locked loop circuit to be within a preset margin range by adjusting a filtering resistor and a filtering capacitor in the filter. This includes pulling back or maintaining the loop parameters that have changed due to external power supply voltage factors, Kvco changes (changes in the output frequency of the voltage-controlled oscillator), changes in the output current of the charge pump, the crystal oscillator signal externally inputted into the phase-locked loop, or the frequency range generated by phase locking, to be within a predetermined margin range. The manner of changing the filtering resistor and the filtering capacitor inside the filter may be performed by the circuit parameter regulator in accordance with the calculation formulas required for the loop parameters. Specific implementation includes switching corresponding numerical levels, which is regarded as level selection operations or parameter adjustment operations. Particularly, when the gain value of the voltage-controlled oscillator changes (e.g., Kvco increases), reducing the resistance value of the filtering resistor inside the filter can not only control the loop parameters generated by the phase-locked loop circuit to be within the preset margin range but also suppress the increase in the area of the phase-locked loop circuit.

The loop parameters of the phase-locked loop in this embodiment include the bandwidth ratio and the damping factor, which achieve control over the frequency and phase accuracy locked by the phase-locked loop, ensuring the stability of the phase-locked loop. Factors measuring the stability of the phase-locked loop include the accuracy of the locked frequency and phase, locking efficiency, oscillation rate, etc.

In this embodiment, the circuit parameter regulator is coupled to the phase-locked loop circuit. The circuit parameter regulator is further used to control the loop parameters generated by the phase-locked loop circuit to be within the preset margin range by adjusting a frequency division coefficient of the pre-frequency divider and/or a frequency of the signal to be processed inputted into the pre-frequency divider, and to reduce a capacitance value of the filtering capacitor in the filter. When adjusting the frequency division coefficient and the frequency of the signal to be processed, it may be performed by switching corresponding numerical levels, regarded as level selection operations or parameter adjustment operations. The signal to be processed inputted into the pre-frequency divider is frequency-divided to form the reference signal inputted into the phase frequency detector, i.e., the signal inputted into the phase-locked loop circuit.

Specifically, in the process where the circuit parameter regulator controls the loop parameters generated by the phase-locked loop circuit to be within the preset margin range by adjusting the filtering resistor and the filtering capacitor in the filter, considering the circuit area, the resistance value of the filtering resistor in the filter will be reduced when the gain value of the voltage-controlled oscillator increases. In that regard, to maintain the loop parameters generated by the phase-locked loop circuit within the preset margin range, the capacitance value of the filtering capacitor inside the filter needs to be greatly increased. To this end, a trade-off is still required in this embodiment. Accordingly, the circuit parameter regulator may continue, based on the calculation formulas required for the loop parameters, to adjust the capacitance value of the filtering capacitor in the filter by changing the frequency division coefficient of the pre-frequency divider and/or the frequency of the signal to be processed inputted into the pre-frequency divider. Thus, while ensuring that the loop parameters generated by the phase-locked loop circuit are within the preset margin range, the capacitance value of the filtering capacitor in the filter is reduced, even smaller than the capacitance value of the filtering capacitor after the last increase, thereby forming a configuration mode for area minimization.

Therefore, this embodiment achieves precise and flexible control of loop parameters by adjusting the capacitance value and resistance value in the loop filter, and/or by adjusting the frequency division coefficient in the pre-frequency divider, and/or by adjusting the frequency of the signal to be processed inputted into the pre-frequency divider, thereby ensuring stable operation of the phase-locked loop. Furthermore, while maintaining the loop parameters within a certain margin range (which maintains stable operation of the phase-locked loop), it enables the configuration that minimizes the area of the phase-locked loop circuit (including the trend toward smaller filter capacitors and filter resistors).

As Embodiment 1, the circuit parameter regulator is used to, when the gain value of the voltage-controlled oscillator increases, reduce the resistance value of the filtering resistor in the filter, to control the bandwidth ratio to be within a first preset margin range; and increase the capacitance value of the filtering capacitor in the filter, to control the damping factor to be within a second preset margin range.

It should be noted that the first preset margin range is different from the second preset margin range. Specifically, the first preset margin range is used to represent a numerical range of the bandwidth ratio, and the second preset margin range is used to represent a numerical range of the damping factor, and the numerical ranges of the two do not overlap. When it is detected that the bandwidth ratio is within the first preset margin range and the damping factor is within the second preset margin range, it is determined that the loop parameters generated by the phase-locked loop circuit are within the preset margin range.

Specifically, in Embodiment 1, based on the calculation formulas of the bandwidth ratio and the damping factor, in order to maintain the bandwidth ratio within the first preset margin range and maintain the damping factor within the second preset margin range, the circuit parameter regulator reduces the resistance value of the filtering resistor in the filter (considered as adjusting the filtering resistor in the filter) while increasing the capacitance value of the filtering capacitor inside the filter (considered as adjusting the filtering capacitor in the filter) in a phase-locked loop working environment where the gain value of the voltage-controlled oscillator increases due to changes in internal model parameter or changes in electrical quantity (supply voltage/current) changes. Moreover, the gain value of the voltage-controlled oscillator increases by a same multiplication factor as the capacitance value of the filtering capacitor. This essentially mitigates the bandwidth ratio, which changes (considered as indicator degradation, i.e., deviation from the first preset margin range) due to the change in the gain value of the voltage-controlled oscillator, by reducing the resistance value of the filtering resistor in the filter. Furthermore, it mitigates the damping factor, which changes (considered as indicator degradation, i.e., deviation from the second preset margin range) due to the change in the gain value of the voltage-controlled oscillator and the change in the filtering resistor, by increasing the capacitance value of the filtering capacitor in the filter. Since both the gain value of the voltage-controlled oscillator and the resistance value of the filtering resistor change within the same damping factor calculation formula, the capacitance value of the filtering capacitor in the filter is not adjusted to increase by a square factor when used in the calculation of the damping coefficient, thereby weakening the compensation effect of the capacitance value of the filtering capacitor in the filter. Specifically, it avoids the need to set a multiplication factor by which the capacitance value of the filtering capacitor is increased to the square of a multiplication factor by which the resistance value of the filtering resistor is reduced, just because the resistance value of the filtering resistor in the filter is reduced. It also addresses the issue of setting excessively large capacitance levels or insufficient capacitance levels in the filter.

It is worth noting that the loop parameters generated by the phase-locked loop circuit include the bandwidth ratio and the damping factor, and the preset margin range includes the first preset margin range and the second preset margin range. An implementation where the capacitance value of the filtering capacitor in the filter is not adjusted to increase by a square factor when used in the calculation of the damping coefficient is, for example, without considering the change in the gain value of the voltage-controlled oscillator, due to that the resistance value of the filtering resistor in the filter is reduced, it needs to set the multiplication factor by which the capacitance value of the filtering capacitor is increased to the square of the multiplication factor by which the resistance value of the filtering resistor in the filter is reduced. Only by doing so can the bandwidth ratio be controlled within the first preset margin range while also maintaining the damping coefficient within the second preset margin range. This would cause the area of the filtering capacitor to increase in a squared-multiple manner, potentially leading to an exponential growth in the area of the phase-locked loop where this filtering capacitor is connected to. Avoiding this issue is one of the key objectives of this application.

On the basis of the above-mentioned embodiments, the circuit parameter regulator is used to reduce the capacitance value of the filtering capacitor in the filter when the loop parameters generated by the phase-locked loop circuit are within the preset margin range, by reducing the frequency division coefficient of the pre-frequency divider or increasing the frequency of the signal to be processed inputted into the pre-frequency divider. Specifically, to maintain the bandwidth ratio within the first preset margin range while also maintaining the damping factor within the second preset margin range, it needs to further reduce the frequency division coefficient of the pre-frequency divider or increase the frequency of the signal to be processed inputted into the pre-frequency divider, so as to provide a redundant range for reducing the capacitance value of the filtering capacitor. Moreover, the remaining circuit parameters (locked signal frequency parameters, bandwidth-related parameters, and charge pump output current-related parameters) under the same damping factor calculation formula remain relatively fixed.

Therefore, when the gain value of the voltage-controlled oscillator changes, the circuit parameter regulator sequentially adjusts the resistance value of the filtering resistor (by selecting capacitance and resistance levels in the filter), the frequency division coefficient of the pre-frequency divider (by selecting frequency division coefficient levels in the pre-frequency divider), and the frequency of the signal to be processed (by selecting signal frequency levels inputted into the pre-frequency divider). Even when some circuit parameters are maintained, the loop parameters can be flexibly controlled and the capacitance value of the filtering capacitor can be adjusted, so as to ensure stable operation of the loop.

As Embodiment 2, the circuit parameter regulator is used to increase the resistance value of the filtering resistor in the filter when the gain value of the voltage-controlled oscillator decreases, to control the bandwidth ratio to be within the first preset margin range; and decrease the capacitance value of the filtering capacitor in the filter, to control the damping coefficient to be within the second preset margin range. The gain value of the voltage-controlled oscillator decreases by a same multiplication factor as the capacitance value of the filtering capacitor. Specifically, based on the calculation formulas of the bandwidth ratio and the damping factor, in order to maintain the bandwidth ratio within the first preset margin range and maintain the damping factor within the second preset margin range, the circuit parameter regulator increases the resistance value of the filtering resistor in the filter (considered as adjusting the filtering resistor in the filter) while reducing the capacitance value of the filtering capacitor inside the filter (considered as adjusting the filtering capacitor in the filter) in a phase-locked loop working environment where the gain value of the voltage-controlled oscillator increases due to changes in internal model parameter or changes in electrical quantity (supply voltage/current) changes. Moreover, a multiplication factor by which the gain value of the voltage-controlled oscillator increases is equal to a multiplication factor by which the capacitance value of the filtering capacitor is reduced. In the same bandwidth ratio calculation formula and the same damping factor calculation formula, other related circuit parameters (including locked signal frequency parameters, bandwidth-related parameters, and charge pump output current-related parameters; the above-mentioned bandwidth ratio and damping factor calculation formulas are formulas associated with the above-mentioned parameters) remain relatively unchanged. Thus, the change in loop parameters (denotes as a change in loop bandwidth) caused by the change in the gain value of the voltage-controlled oscillator is controllable for the circuit parameter regulator. The implementation of maintaining the stability of the phase-locked loop by adjusting the filtering resistor and the filtering capacitor is feasible.

As Embodiment 3, the circuit parameter regulator is used to determine that the gain value of the voltage-controlled oscillator increases, the resistance value of the filtering resistor in the filter is reduced, and the capacitance value of the filtering capacitor in the filter is increased, so that the calculated loop parameter of the phase-locked loop is within the preset margin range. This essentially means that, after the gain value of the voltage-controlled oscillator increases, the bandwidth ratio returns to the first preset margin range for the first time, and the damping factor returns to the second preset margin range for the first time.

In the same damping factor calculation formula, after the resistance value of the filtering resistor is reduced, a multiplication factor by which a value inside the square root in the damping factor calculation formula is increased needs to be configured as the square of the multiplication factor by which the resistance value of the filtering resistor is reduced, which is also equal to the square of the multiplication factor by which the gain value of the voltage-controlled oscillator increases. In order to maintain the stability of the bandwidth ratio and the damping factor, the increase in the capacitance value of the filtering capacitor brings a large increase to the circuit area of the phase-locked loop. This embodiment compensates for the increase in the capacitance value by the frequency division coefficient. In the case where the frequency of the signal to be processed is maintained and the frequency division coefficient of the pre-frequency divider is reduced, the capacitance value of the filtering capacitor in the filter is reduced, so as to control the damping factor to be within the second preset margin range while maintaining the bandwidth ratio. In the damping factor calculation formula, the frequency division coefficient of the pre-frequency divider is reduced by a same multiplication factor as the capacitance value of the filtering capacitor, so as to maintain the damping factor. Thus, the reduced frequency division coefficient of the pre-frequency divider, the decreased resistance value of the filtering resistor, and the reduced capacitance value of the filtering capacitor form a small-area configuration of the phase-locked loop circuit. In addition, under the same damping factor calculation formula, the frequency division coefficient of the pre-frequency divider is reduced by a same multiplication factor as the frequency division coefficient of the loop frequency divider, so that the frequency of the signal inputted into the loop frequency divider is maintained. In actual adjustment, a reference frequency inputted into the pre-frequency divider (or a reference signal inputted into the phase-locked loop) is usually fixed. Therefore, even when the filtering resistor and the gain value of the voltage-controlled oscillator have been selected, it is still able to flexibly adjust the area used by the capacitor and control the bandwidth ratio and damping factor within fixed margins by adjusting the relevant frequency division coefficients, forming a trade-off adjustment mode between the phase-locked loop circuit area and the phase-locked loop working stability. Further, manufacturing the chip circuit unit according to the circuit parameters configured in this trade-off adjustment mode enables significant savings in chip area.

After determining that the gain value of the voltage-controlled oscillator increases, the resistance value of the filtering resistor in the filter is reduced, and the capacitance value of the filtering capacitor in the filter is increased, so that the calculated loop parameter of the phase-locked loop is within the preset margin range, the circuit parameter regulator is further used to determine that the current bandwidth ratio is within the first preset margin range and the current damping factor is within the second preset margin range. In the same damping factor calculation formula, after the resistance value of the filtering resistor is reduced, a multiplication factor by which a value inside the square root in the damping factor calculation formula is increased needs to be configured as the square of the multiplication factor by which the resistance value of the filtering resistor is reduced, which is also equal to the square of the multiplication factor by which the gain value of the voltage-controlled oscillator increases. At this point, the increase in the capacitance value of the filtering capacitor, which acts as compensation, brings a large increase to the circuit area of the phase-locked loop. A multiplication factor by which the capacitance value is increased may be equal to a multiplication factor by which the resistance value is reduced, and also equal to the multiplication factor by which the gain value of the voltage-controlled oscillator increases. This embodiment offsets the increase in the capacitance value by adjusting the frequency of the signal to be processed. In the case where the frequency of the signal to be processed is increased and the frequency division coefficient of the pre-frequency divider is maintained, the capacitance value of the filtering capacitor in the filter is reduced, so as to control the damping factor to be within the second preset margin range while maintaining the bandwidth ratio. The multiplication factor by which the frequency of the signal to be processed is increased is equal to the multiplication factor by which the capacitance value of the filtering capacitor is reduced, which can reduce the occupied area of the filtering capacitor, allowing the phase-locked loop circuit to operate stably with a small area occupied by the filter capacitor as much as possible. In addition, under the same damping factor calculation formula, the capacitance value of the filtering capacitor is reduced by a same multiplication factor as the frequency division coefficient of the loop frequency divider, so that the frequency of the signal inputted into the loop frequency divider is maintained. The pre-frequency divider is used to frequency-divide the external input signal to be processed into a reference signal and input the reference signal to the phase frequency detector. When the frequency division coefficient of the pre-frequency divider remains unchanged and the frequency of the signal to be processed increases, the frequency of the reference signal increases. To maintain the frequency of the signal inputted into the loop frequency divider, the frequency of the reference signal needs to be reduced. Thus, the multiplication factor by which the frequency division coefficient of the loop frequency divider is reduced is set to the multiplication factor by which the capacitance value of the filtering capacitor is reduced.

In summary, when adjusting and obtaining the circuit parameter configuration that meets the accuracy requirements of the loop parameters and the area requirements of the phase-locked loop circuit through the circuit parameter regulator, including the frequency of the signal to be processed, the frequency division coefficients, the capacitance value of the filtering capacitor, and the resistance value of the filtering resistor, manufacturing the chip circuit unit according to this circuit parameter configuration can save chip area and ensure the working stability of the phase-locked loop.

As Embodiment 4, the circuit parameter regulator is used to determine that the gain value of the voltage-controlled oscillator increases, the resistance value of the filtering resistor in the filter is reduced, and the capacitance value of the filtering capacitor in the filter is increased, so that the calculated loop parameter of the phase-locked loop is within the preset margin range. This essentially means that, after the gain value of the voltage-controlled oscillator increases, the capacitance value of the filtering capacitor is adjusted on the basis of the decrease in the resistance value of the filtering resistor in the filter through the adjustment by the circuit parameter regulator, causing the bandwidth ratio to return to the first preset margin range for the first time, and the damping factor to return to the second preset margin range for the first time. At this point, the increase in the capacitance value of the filtering capacitor brings a large increase to the area of the phase-locked loop circuit, requiring the frequency division coefficient and the frequency of the signal to be processed together to compensate for the increase in the capacitance value. In the case where the frequency of the signal to be processed is increased and the frequency division coefficient of the pre-frequency divider is reduced, the capacitance value of the filtering capacitor in the filter is reduced, so as to control the damping factor to be within the second preset margin range. Further, the bandwidth ratio is maintained and the gain value of the voltage-controlled oscillator has been determined, the circuit parameter regulator brings the bandwidth ratio back within the first preset margin range again and the damping factor back within the second preset margin range again. Since both the frequency of the signal to be processed and the frequency division coefficient of the pre-frequency divider change under the same damping factor calculation formula, the product of the multiplication factor by which the frequency division coefficient of the pre-frequency divider is reduced and the multiplication factor by which the frequency of the signal to be processed is increased is equal to the multiplication factor by which the capacitance value of the filtering capacitor is reduced. Therefore, as compared with the Embodiments 1 to 3, the circuit parameter regulator in Embodiment 4 reduces the capacitance value of the filtering capacitor by a greater magnitude, thereby reducing the area of the phase-locked loop circuit to which it is connected. Alternatively, the circuit parameters composed of the finally adjusted frequency of the signal to be processed, frequency division coefficients, capacitance value of the filtering capacitor, and resistance value of the filtering resistor correspond to a phase-locked loop circuit configuration with a larger reduction in area.

In addition, in the same damping factor calculation formula, the product of the multiplication factor by which the frequency division coefficient of the pre-frequency divider is reduced and the multiplication factor by which the frequency of the signal to be processed is increased is equal to the multiplication factor by which the frequency division coefficient of the loop frequency divider is reduced, so that the frequency of the signal inputted into the loop frequency divider is maintained. The pre-frequency divider is used to frequency-divide the external input signal to be processed into a reference signal and input the reference signal to the phase frequency detector. When the frequency division coefficient of the pre-frequency divider decreases and the frequency of the signal to be processed increases, the frequency of the reference signal increases. Regardless of whether the frequency division coefficient of the pre-frequency divider decreases or the frequency of the signal to be processed increases, the frequency of the reference signal increases. To maintain the frequency of the signal inputted into the loop frequency divider, the frequency of the reference signal needs to be reduced by corresponding factors which are made for the decrease in the frequency division coefficient and the increase in the frequency of the signal to be processed, respectively. Hence, the multiplication factor by which the frequency division coefficient of the loop frequency divider is reduced is set as the product of the multiplication factor by which the frequency division coefficient of the pre-frequency divider is reduced and the multiplication factor by which the frequency of the signal to be processed is increased.

As Embodiment 5, the circuit parameter regulator is used to: reduce the resistance value of the filtering resistor in the filter when the gain value of the voltage-controlled oscillator increases, to control a bandwidth ratio to be within a first preset margin range; where a multiplication factor by which the resistance value of the filtering resistor is decreased is equal to a multiplication factor by which the gain value of the voltage-controlled oscillator increases; and reduce the frequency division coefficient of the pre-frequency divider and reduce the capacitance value of the filtering capacitor in the filter, to control a damping coefficient to be within a second preset margin range. A ratio of a multiplication factor by which the frequency division coefficient of the pre-frequency divider is reduced to a multiplication factor by which the capacitance value of the filtering capacitor is reduced is equal to a multiplication factor by which the gain value of the voltage-controlled oscillator increases, and the multiplication factor by which the frequency division coefficient of the pre-frequency divider is reduced is greater than the multiplication factor by which the capacitance value of the filtering capacitor is reduced. In specific, the circuit parameter regulator reduces the resistance value of the filtering resistor in the filter (considered as adjusting the filtering resistor in the filter) in a phase-locked loop working environment where the gain value of the voltage-controlled oscillator increases due to changes in internal model parameter or changes in electrical quantity (supply voltage/current) changes. Moreover, the multiplication factor by which the gain value of the voltage-controlled oscillator increases is equal to the multiplication factor by which the resistance value of the filtering resistor is reduced. This essentially mitigates the bandwidth ratio, which changes (considered as indicator degradation, i.e., deviation from the first preset margin range) due to the change in the gain value of the voltage-controlled oscillator, by reducing the resistance value of the filtering resistor in the filter. Furthermore, considering the circuit area, the capacitance value of the filtering capacitor inside the filter is reduced. Specifically, this mitigates the damping factor, which changes (considered as indicator degradation, i.e., deviation from the second preset margin range) due to the change in the gain value of the voltage-controlled oscillator and the change in the filtering resistor, by decreasing the capacitance value of the filtering capacitor in the filter. Since both the gain value of the voltage-controlled oscillator and the resistance value of the filtering resistor change within the same damping factor calculation formula, this embodiment reduces the frequency division coefficient of the pre-frequency divider. In the same damping factor calculation formula, after the resistance value of the filtering resistor is reduced, a multiplication factor by which a value in the square root in the damping factor calculation formula is increased needs to be configured as the square of the multiplication factor by which the resistance value of the filtering resistor is reduced, which is also equal to the square of the multiplication factor by which the gain value of the voltage-controlled oscillator increases. At this point, reducing the frequency division coefficient of the pre-frequency divider essentially increases the value in the square root in the damping factor calculation formula, so as to provide a large redundant range for reducing the capacitance value of the filtering capacitor. Moreover, the remaining circuit parameters (locked signal frequency parameters, bandwidth-related parameters, and charge pump output current-related parameters) in the same damping factor calculation formula remain relatively fixed. The ratio of the multiplication factor by which the frequency division coefficient of the pre-frequency divider is reduced to the multiplication factor by which the capacitance value of the filtering capacitor is reduced is equal to the multiplication factor by which the gain value of the voltage-controlled oscillator increases, the multiplication factor by which the frequency division coefficient of the pre-frequency divider is reduced is greater than the multiplication factor by which the capacitance value of the filtering capacitor is reduced, and the multiplication factor by which the gain value of the voltage-controlled oscillator increases is preferably greater than 1. Therefore, to avoid the increase in the capacitance value of the filtering capacitor bringing a large increase to the area of the phase-locked loop circuit, this embodiment suppresses the impact of the reduction in the resistance value on the phase-locked loop through the reduction amount of the frequency division coefficient and the reduction amount of the capacitance value. Specifically, it avoids the need to set a multiplication factor by which the capacitance value of the filtering capacitor is increased to the square of a multiplication factor by which the resistance value of the filtering resistor is reduced due to that the resistance value of the filtering resistor in the filter is reduced. It also addresses the issue of setting excessively large capacitance levels or insufficient capacitance levels in the filter, and allows the increased gain value of the voltage-controlled oscillator, the decreased resistance value of the filtering resistor, the reduced frequency division coefficient of the pre-frequency divider, and the reduced capacitance value of the filtering capacitor to form a small-area configuration of the phase-locked loop circuit.

Moreover, in the same damping factor calculation formula, the frequency division coefficient of the loop frequency divider is reduced by the same multiplication factor as the capacitance value of the filtering capacitor, so as to maintain the frequency of the signal inputted into the loop frequency divider. In actual adjustment, a reference frequency inputted into the pre-frequency divider (or a reference signal inputted into the phase-locked loop) is usually fixed. Therefore, even when some circuit parameters have been selected, it is still able to flexibly adjust the area used by the capacitor and control the bandwidth ratio and damping factor within fixed margins by adjusting the relevant frequency division coefficients, forming a trade-off adjustment mode between the phase-locked loop circuit area and the phase-locked loop working stability. Further, manufacturing the chip circuit unit according to the circuit parameters configured in this trade-off adjustment mode enables significant savings in chip area.

It should be noted that the first preset margin range is different from the second preset margin range. Specifically, the first preset margin range is used to represent a numerical range of the bandwidth ratio, and the second preset margin range is used to represent a numerical range of the damping factor, and the numerical ranges of the two do not overlap. When it is detected that the bandwidth ratio is within the first preset margin range and the damping factor is within the second preset margin range, it is determined that the loop parameters generated by the phase-locked loop circuit are within the preset margin range.

As Embodiment 6, the circuit parameter regulator is used to: increase the resistance value of the filtering resistor in the filter when the gain value of the voltage-controlled oscillator decreases, to control the bandwidth ratio to be within the first preset margin range, where a multiplication factor by which the resistance value of the filtering resistor is increased is equal to a multiplication factor by which the gain value of the voltage-controlled oscillator decreases; and reduce the frequency division coefficient of the pre-frequency divider, and reduce the capacitance value of the filtering capacitor in the filter, to control the damping coefficient to be within the second preset margin range. A ratio of the multiplication factor by which the capacitance value of the filtering capacitor is reduced to the multiplication factor by which the frequency division coefficient of the pre-frequency divider is reduced is equal to the multiplication factor by which the gain value of the voltage-controlled oscillator decreases, and the multiplication factor by which the frequency division coefficient of the pre-frequency divider is reduced is less than the multiplication factor by which the capacitance value of the filtering capacitor is reduced. The loop parameter generated by the phase-locked loop circuit includes the bandwidth ratio and the damping coefficient; the preset margin range includes the first preset margin range and the second preset margin range, and the first preset margin range is different from the second preset margin range. When the bandwidth ratio is within the first preset margin range and the damping coefficient is within the second preset margin range, the loop parameter generated by the phase-locked loop circuit is within the preset margin range. In specific, the circuit parameter regulator increases the resistance value of the filtering resistor in the filter (considered as adjusting the filtering resistor in the filter) in a phase-locked loop working environment where the gain value of the voltage-controlled oscillator decreases due to changes in internal model parameter or changes in electrical quantity (supply voltage/current) changes. Moreover, the multiplication factor by which the gain value of the voltage-controlled oscillator increases is equal to the multiplication factor by which the resistance value of the filtering resistor is increased. This essentially mitigates the bandwidth ratio, which changes (considered as indicator degradation, i.e., deviation from the first preset margin range) due to the change in the gain value of the voltage-controlled oscillator, by increasing the resistance value of the filtering resistor in the filter. Furthermore, considering the circuit area, the capacitance value of the filtering capacitor in the filter is reduced. Specifically, this mitigates the damping factor, which changes (considered as indicator degradation, i.e., deviation from the second preset margin range) due to the change in the gain value of the voltage-controlled oscillator and the change in the filtering resistor, by decreasing the capacitance value of the filtering capacitor in the filter. Since both the gain value of the voltage-controlled oscillator and the resistance value of the filtering resistor change within the same damping factor calculation formula, this embodiment reduces the frequency division coefficient of the pre-frequency divider. In the same damping factor calculation formula, after the resistance value of the filtering resistor is increased, a multiplication factor by which a value in the square root in the damping factor calculation formula is reduced needs to be configured as the square of the multiplication factor by which the resistance value of the filtering resistor is increased, which is also equal to the square of the multiplication factor by which the gain value of the voltage-controlled oscillator decreases. At this point, reducing the frequency division coefficient of the pre-frequency divider essentially increases the value in the square root in the damping factor calculation formula, so as to provide a large redundant range for reducing the capacitance value of the filtering capacitor. Moreover, the remaining circuit parameters (locked signal frequency parameters, bandwidth-related parameters, and charge pump output current-related parameters) in the same damping factor calculation formula remain relatively fixed. The ratio of the multiplication factor by which the capacitance value of the filtering capacitor is reduced to the multiplication factor by which the frequency division coefficient of the pre-frequency divider is reduced is equal to the multiplication factor by which the gain value of the voltage-controlled oscillator decreases, the multiplication factor by which the frequency division coefficient of the pre-frequency divider is reduced is less than the multiplication factor by which the capacitance value of the filtering capacitor is reduced, and the multiplication factor by which the gain value of the voltage-controlled oscillator increases is preferably greater than 1. Therefore, to increase the multiplication factor by which the capacitance value of the filtering capacitor is reduced, this embodiment needs to compensate for the stability of the phase-locked loop operation caused by the decrease in the gain value of the voltage-controlled oscillator and the increase in the resistance value of the filtering resistor (representing an increasing amount of the value in the square root in the damping factor calculation formula) by reducing the frequency division coefficient and reducing the capacitance value. Moreover, the multiplication factor by which the capacitance value of the filtering capacitor is reduced is greater than the multiplication factor by which the frequency division coefficient of the pre-frequency divider is reduced, so as to compensate/balance the area increase caused by the increase in the resistance value of the filtering resistor in the filter.

As Embodiment 7, the circuit parameter regulator is used to: reduce the resistance value of the filtering resistor in the filter when the gain value of the voltage-controlled oscillator increases, to control a bandwidth ratio to be within a first preset margin range, where a multiplication factor by which the resistance value of the filtering resistor is decreased is equal to a multiplication factor by which the gain value of the voltage-controlled oscillator increases; and increase the frequency of the signal to be processed, and reduce the capacitance value of the filtering capacitor in the filter, to control a damping coefficient to be within a second preset margin range. The frequency division coefficient of the pre-frequency divider is maintained, a ratio of a multiplication factor by which the frequency of the signal to be processed is increased to a multiplication factor by which the capacitance value of the filtering capacitor is reduced is equal to a multiplication factor by which the gain value of the voltage-controlled oscillator increases, and the multiplication factor by which the frequency of the signal to be processed is increased is greater than the multiplication factor by which the capacitance value of the filtering capacitor is reduced. This causes the product of the frequency of the signal to be processed and the capacitance value of the filtering capacitor to increase after adjustment, but the increase amplitude thereof is less than the amplitude of the increase of the frequency of the signal to be processed alone. This is because a multiplication factor by which the product of the frequency of the signal to be processed and the capacitance value of the filtering capacitor increases is controlled by reducing the capacitance value of the filter capacitor to be equal to the multiplication factor by which the gain value of the voltage-controlled oscillator increases. The influence of reducing the resistance value is offset, and the damping coefficient is controlled to be within the second preset margin range, and the bandwidth ratio is within the first preset margin range. The phase-locked loop is guaranteed to work stably. Moreover, the capacitance value and the resistance value are reduced, and manufacturing the chip circuit unit according to the configured circuit parameters enables significant savings in chip area.

In specific, the circuit parameter regulator reduces the resistance value of the filtering resistor in the filter (considered as adjusting the filtering resistor in the filter) in a phase-locked loop working environment where the gain value of the voltage-controlled oscillator increases due to changes in internal model parameter or changes in electrical quantity (supply voltage/current) changes. Moreover, the multiplication factor by which the gain value of the voltage-controlled oscillator increases is equal to the multiplication factor by which the resistance value of the filtering resistor is reduced. This essentially mitigates the bandwidth ratio, which changes (considered as indicator degradation, i.e., deviation from the first preset margin range) due to the change in the gain value of the voltage-controlled oscillator, by reducing the resistance value of the filtering resistor in the filter. Furthermore, considering the circuit area, the capacitance value of the filtering capacitor inside the filter is reduced. Specifically, this mitigates the damping factor, which changes (considered as indicator degradation, i.e., deviation from the second preset margin range) due to the change in the gain value of the voltage-controlled oscillator and the change in the filtering resistor, by decreasing the capacitance value of the filtering capacitor in the filter. Since both the gain value of the voltage-controlled oscillator and the resistance value of the filtering resistor change within the same damping factor calculation formula, this embodiment increases the frequency of the signal to be processed while maintaining the frequency division coefficient of the pre-frequency divider. In the same damping factor calculation formula, after the resistance value of the filtering resistor is reduced, a multiplication factor by which a value in the square root in the damping factor calculation formula is increased needs to be configured as the square of the multiplication factor by which the resistance value of the filtering resistor is reduced, which is also equal to the square of the multiplication factor by which the gain value of the voltage-controlled oscillator increases. At this point, increasing the frequency of the signal to be processed essentially increases the value in the square root in the damping factor calculation formula, and the multiplication factor by which the frequency of the signal to be processed is increased is greater than the multiplication factor by which the capacitance value of the filtering capacitor is reduced, thereby necessitating a reduction in the capacitance value of the filtering capacitor. Moreover, the remaining circuit parameters (locked signal frequency parameters, bandwidth-related parameters, and charge pump output current-related parameters) in the same damping factor calculation formula remain relatively fixed. The ratio of the multiplication factor by which the frequency of the signal to be processed is increased to the multiplication factor by which the capacitance value of the filtering capacitor is reduced is equal to the multiplication factor by which the gain value of the voltage-controlled oscillator increases, the multiplication factor by which the frequency of the signal to be processed is increased is greater than the multiplication factor by which the capacitance value of the filtering capacitor is reduced, and the multiplication factor by which the gain value of the voltage-controlled oscillator increases is preferably greater than 1.

Therefore, to avoid the increase in the capacitance value of the filtering capacitor bringing a large increase to the area of the phase-locked loop circuit, this embodiment compensates for the change in capacitance value by adjusting the frequency of the signal to be processed. Specifically, it avoids the need to set the multiplication factor by which the capacitance value of the filtering capacitor is increased to the square of the multiplication factor by which the resistance value of the filtering resistor is reduced due to that the resistance value of the filtering resistor in the filter is reduced. It also addresses the issue of setting excessively large capacitance levels or insufficient capacitance levels in the filter, and allows the increased gain value of the voltage-controlled oscillator, the decreased resistance value of the filtering resistor, the increased frequency of the signal to be processed, and the reduced capacitance value of the filtering capacitor to form a small-area configuration of the phase-locked loop circuit. In addition, the circuit parameters of the phase-locked loop can be flexibly adjusted to ensure stable operation of the loop.

Moreover, in the same damping factor calculation formula, the multiplication factor by which the frequency of the signal to be processed is increased is euqal to the multiplication factor by which the frequency division coefficient of the loop frequency divider, so as to maintain the frequency of the signal inputted into the loop frequency divider. In actual adjustment, even when some circuit parameters have been selected, it is still able to flexibly adjust the area used by the capacitor and control the bandwidth ratio and damping factor within fixed margins by adjusting the frequency of the signal to be processed, forming a trade-off adjustment mode between the phase-locked loop circuit area and the phase-locked loop working stability. Further, manufacturing the chip circuit unit according to the circuit parameters configured in this trade-off adjustment mode enables significant savings in chip area.

It should be noted that the first preset margin range is different from the second preset margin range. Specifically, the first preset margin range is used to represent a numerical range of the bandwidth ratio, and the second preset margin range is used to represent a numerical range of the damping factor, and the numerical ranges of the two do not overlap. When it is detected that the bandwidth ratio is within the first preset margin range and the damping factor is within the second preset margin range, it is determined that the loop parameters generated by the phase-locked loop circuit are within the preset margin range.

As Embodiment 8, the circuit parameter regulator is used to: increase the resistance value of the filtering resistor in the filter when the gain value of the voltage-controlled oscillator decreases, to control the bandwidth ratio to be within the first preset margin range, where a multiplication factor by which the resistance value of the filtering resistor is increased is equal to a multiplication factor by which the gain value of the voltage-controlled oscillator decreases; and increase the frequency-division coefficient of the pre-frequency divider, and reduce the capacitance value of the filtering capacitor in the filter, to control the damping coefficient to be within the second preset margin range. A ratio of the multiplication factor by which the capacitance value of the filtering capacitor is reduced to the multiplication factor by which the frequency of the signal to be processed is increased is equal to the multiplication factor by which the gain value of the voltage-controlled oscillator decreases, and the multiplication factor by which the frequency of the signal to be processed is increased is less than the multiplication factor by which the capacitance value of the filtering capacitor is reduced. This causes the product of the frequency of the signal to be processed and the capacitance value of the filtering capacitor to increase after adjustment, but the increase amplitude thereof is less than the amplitude of the decrease of the capacitance value of the filtering capacitor alone. This is because an equivalent multiplication factor by which the product of the frequency of the signal to be processed and the capacitance value of the filtering capacitor decreases is controlled by reducing the capacitance value of the filter capacitor to be equal to the multiplication factor by which the gain value of the voltage-controlled oscillator increases. The loop parameter generated by the phase-locked loop circuit includes the bandwidth ratio and the damping coefficient, the preset margin range includes the first preset margin range and the second preset margin range, and the first preset margin range is different from the second preset margin range. When the bandwidth ratio is within the first preset margin range and the damping coefficient is within the second preset margin range, the loop parameter generated by the phase-locked loop circuit is within the preset margin range.

In specific, the circuit parameter regulator increases the resistance value of the filtering resistor in the filter (considered as adjusting the filtering resistor in the filter) in a phase-locked loop working environment where the gain value of the voltage-controlled oscillator decreases due to changes in internal model parameter or changes in electrical quantity (supply voltage/current) changes. Moreover, the multiplication factor by which the gain value of the voltage-controlled oscillator decreases is equal to the multiplication factor by which the resistance value of the filtering resistor is increased. This essentially mitigates the bandwidth ratio, which changes (considered as indicator degradation, i.e., deviation from the first preset margin range) due to the change in the gain value of the voltage-controlled oscillator, by increasing the resistance value of the filtering resistor in the filter. Furthermore, considering the circuit area, the capacitance value of the filtering capacitor inside the filter is reduced. Specifically, this mitigates the damping factor, which changes (considered as indicator degradation, i.e., deviation from the second preset margin range) due to the change in the gain value of the voltage-controlled oscillator and the change in the filtering resistor, by decreasing the capacitance value of the filtering capacitor in the filter. Since both the gain value of the voltage-controlled oscillator and the resistance value of the filtering resistor change within the same damping factor calculation formula, this embodiment increases the frequency of the signal to be processed.

In the same damping factor calculation formula, after the resistance value of the filtering resistor is increased, a multiplication factor by which a value in the square root in the damping factor calculation formula is reduced needs to be configured as the square of the multiplication factor by which the resistance value of the filtering resistor is increased, which is also equal to the square of the multiplication factor by which the gain value of the voltage-controlled oscillator decreases. At this point, increasing the frequency of the signal to be processed essentially increases the value in the square root in the damping factor calculation formula, so as to provide a large redundant range for reducing the capacitance value of the filtering capacitor. Moreover, the remaining circuit parameters (locked signal frequency parameters, bandwidth-related parameters, and charge pump output current-related parameters) in the same damping factor calculation formula remain relatively fixed. The ratio of the multiplication factor by which the capacitance value of the filtering capacitor is reduced to the multiplication factor by which the frequency of the signal to be processed is increased is equal to the multiplication factor by which the gain value of the voltage-controlled oscillator decreases, the multiplication factor by which the frequency of the signal to be processed is increased is less than the multiplication factor by which the capacitance value of the filtering capacitor is reduced, and the multiplication factor by which the gain value of the voltage-controlled oscillator decreases is preferably greater than 1. Therefore, to increase the multiplication factor by which the capacitance value of the filtering capacitor is reduced, this embodiment compensates for the stability of the phase-locked loop operation caused by the decrease in the gain value of the voltage-controlled oscillator and the increase in the resistance value of the filtering resistor (representing an increasing amount of the value in the square root in the damping factor calculation formula) by increasing the frequency of the signal to be processed and reducing the capacitance value. Moreover, the multiplication factor by which the capacitance value of the filtering capacitor is reduced is greater than the multiplication factor by which the frequency of the signal to be processed is increased, so as to compensate/balance the area increase caused by the increase in the resistance value of the filtering resistor in the filter.

In the foregoing embodiments, a frequency division manner of the pre-frequency divider is to calculate a ratio of the frequency of the signal inputted into the pre-frequency divider to the frequency division coefficient of the pre-frequency divider, to obtain a frequency of the signal after frequency division, so that the pre-frequency divider uses the frequency division coefficient as a scaling-down factor to perform frequency division operation on the signal. The frequency division coefficient of the pre-frequency divider is a positive integer, which is determined by a counting modulus value of a counter set in the pre-frequency divider, and is adjustable in response to a corresponding trigger signal from the circuit parameter regulator. The signal inputted into the pre-frequency divider is generated by a crystal oscillator, which can generate crystal oscillator signals of multiple frequencies. The crystal oscillator may be considered as part of the phase-locked loop working system or located outside the phase-locked loop working system. A frequency division manner of the loop frequency divider is to calculate a ratio of the frequency of the signal inputted into the loop frequency divider to the frequency division coefficient of the loop frequency divider, to obtain a frequency of an output signal of the phase-locked loop, i.e., a frequency of an output signal of the loop frequency divider, and feed it back to the phase frequency detector. The frequency of the signal inputted into the loop frequency divider is equal to the product of the frequency of the signal after frequency division by the pre-frequency divider and the frequency division coefficient of the loop frequency divider. The frequency division coefficient of the loop frequency divider is a positive integer, which is determined by the counting modulus value of the counter set in the loop frequency divider, and is adjustable in response to the trigger signal from the circuit parameter regulator. The frequency of the output signal of the loop frequency divider is equal to the frequency of the signal after the frequency division by the pre-frequency divider. The circuit parameter regulator may simultaneously adjust the frequency division coefficient of the pre-frequency divider and the frequency division coefficient of the loop frequency divider. Regardless of whether the frequency of the signal to be processed increases, it is able to concurrently increase or decrease the frequency division coefficient of the pre-frequency divider and the frequency division coefficient of the loop frequency divider. This capability is crucial for a scenario: when the loop parameters generated by the phase-locked loop circuit are within the preset margin range, the capacitance value of the filtering capacitor is adjusted towards a decreasing direction, saving the chip area, while ensuring the working stability of the phase-locked loop and the accuracy of the locked frequency.

As one embodiment, the filter is provided with a preset quantity of resistance levels and a preset quantity of capacitance levels, each resistance level has a matching capacitance level, and corresponding filtering resistor and filtering capacitor are connected in series. Referring to FIG. 2, resistor R1 and capacitor C1 can be connected in series to form a combination of one resistance level and one capacitance level, or resistor R1 and capacitor C2 can be connected in series to form a combination of one resistance level and one capacitance level, or resistor R2 and capacitor C2 can be connected in series to form a combination of one resistance level and one capacitance level. The combination manner of resistance and capacitance levels is not particularly defined herein. The circuit parameter regulator is used to output a control code to the filter, where the preset quantity is greater than or equal to 2. The control code may be a multi-bit digital encoded signal, for example, a digital encoded signal with twice the preset quantity of bits. One capacitance level is controlled by a one-bit digital encoded signal, and one resistance level is controlled by a one-bit digital encoded signal, thereby to enable the filtering resistor at the relevant resistance level and the filtering capacitor at the relevant capacitance level to be connected into the phase-locked loop circuit, while considering the capacitor area issue (essentially an issue of adjusting the capacitance value size). In particular, when the circuit parameter regulator detects a trigger signal for level switching, it outputs a new control code to the filter, so as to enable the filtering resistor at the new resistance level and the filtering capacitor at the new capacitance level to be connected into the phase-locked loop circuit. Specifically, the circuit parameter regulator, which is coupled to the filter, is used to, upon receiving the control code, switch the resistance level to change the resistance value of the filtering resistor in the filter, and switch the capacitance level to change the capacitance value of the filtering capacitor in the filter, thereby to switch to a new set of resistor-capacitor filter arrays in the filter. The trigger signal for level switching is caused by a change in the gain value of the voltage-controlled oscillator. The circuit parameter regulator controls the loop parameters generated by the phase-locked loop circuit to be within the preset margin range by switching the capacitance level and the resistance level, and preferably reduces the capacitance value of the filtering capacitor in the filter.

As one embodiment, the control code includes a capacitance control code corresponding to the capacitance value and a resistance control code corresponding to the resistance value. The filter includes a preset quantity of candidate capacitors, a preset quantity of candidate resistors, a reference capacitor and twice the preset quantity of switch circuits. As shown in FIG. 2, the preset number is equal to m. The preset quantity of candidate capacitors is C1, C2, . . . , Cm. The preset quantity of candidate resistors is R1, R2, . . . , Rm. The reference capacitor is Cp. Twice the preset quantity of switch circuits are S11, S12, . . . , SIm between the charge pump and the resistors, and S21, S22, . . . , S2m between the resistors and the capacitors in FIG. 2. A first end of each candidate resistor is coupled to an output end of the charge pump through one switch circuit, a second end of each candidate resistor is coupled to a first end of one corresponding candidate capacitor through one switch circuit, and a second end of each candidate capacitor is coupled to the ground. A first end of the reference capacitor Cp is coupled to the output end of the charge pump, and a second end of the reference capacitor Cp is coupled to the ground, and the first end of the reference capacitor Cp is further coupled to an input end of the voltage-controlled oscillator. A second end of each candidate resistor is coupled together. This makes it possible for resistor R1 and capacitor C2 to be connected in series to the phase-locked loop circuit, and also for resistor R1 and capacitor C1 to be connected in series to the phase-locked loop circuit. This allows the same resistance level to be connected in series with multiple different capacitance levels to the phase-locked loop circuit, thereby forming different resistor-capacitor matching modes, providing more circuit parameter selection ranges for the circuit parameter regulator, and enhancing the anti-interference capability of the phase-locked loop circuit against the gain value of the voltage-controlled oscillator, the output current of the charge pump, and the loop bandwidth. In other words, the parameter adjustment range of maintaining the stable operation of the phase-locked loop circuit is effectively expanded.

The resistance control code corresponding to the resistance value outputted by the circuit parameter adjuster is used to control the switch circuit coupled between the first end of the candidate resistor and the output end of the charge pump to be in an ON or OFF state. The switch circuits coupled between the first ends of the candidate resistors and the output end of the charge pump correspond to S11, S12, . . . , SIm in FIG. 2. The resistance control code may be denoted as SR[m−1:0]. Specifically, resistance control code SR[m−1] controls switch circuit S11, resistance control code SR[m−2] controls switch circuit S12, and so on. Resistance control code SR[0] controls switch circuit Slm. Thus, the resistance control codes are traversed in order from the most significant bit (MSB) to the least significant bit (LSB), thereby sequentially controlling the switch circuits in FIG. 2 from left to right. When the switch circuit coupled between the first end of the candidate resistor and the output end of the charge pump is in an on state, it indicates that the candidate resistor connected to the switch circuit in the ON state is selected, the selected candidate resistor is determined as the filtering resistor in the filter, and it is determined that the filter switches to the resistance level corresponding to the resistance control code. For example, when m=4, the resistance control code may be denoted as SR[3:0]. When the resistance control code SR[3:0]=1000, the switch circuit S11 coupled between the first end of candidate resistor R1 and the output terminal of the charge pump is in an ON state, it indicates that candidate resistor R1 connected to switch circuit S11 is selected, the candidate resistor R1 is determined as the filtering resistor in the filter, and it is determined that the filter switches to the resistance level corresponding to the resistance control code SR[3:0].

The capacitance control code corresponding to the capacitance value outputted by the circuit parameter adjuster is used to control the switch circuit coupled between the first end of the candidate capacitor and the second end of the candidate resistor to be in ON or OFF state. The switch circuits coupled between first ends of the candidate capacitors and second ends of the candidate resistors correspond to S21, S22, . . . , S2m in FIG. 2. The capacitance control code may be denoted as SC[m−1:0]. Specifically, capacitance control code SC[m−1] controls switch circuit S21, capacitance control code SC[m−2] controls switch circuit S22, and so on. Capacitance control code SC[0] controls switch circuit S2m. Thus, the capacitance control codes are traversed in order from the most significant bit (MSB) to the least significant bit (LSB), thereby sequentially controlling the switch circuits in FIG. 2 from left to right. When the switch circuit coupled between the first end of the candidate capacitor and the second end of the candidate resistor is in an ON state, it indicates that the candidate capacitor connected to the switch circuit in the ON state is selected, and the selected candidate capacitor is determined as the filtering capacitor in the filter, and it is determined that the filter switches to the capacitance level corresponding to the capacitance control code. For example, when m=4, the capacitance control code may be denoted as SC[3:0]. When the capacitance control code SC[3:0]=1000, the switch circuit S21 coupled between the first end of candidate capacitor C1 and the output terminal of the charge pump is in an ON state, it indicates that candidate capacitor C1 connected to switch circuit S21 is selected, candidate capacitor C1 is determined as the filtering resistor C1 in the filter, and it is determined that the filter switches to the capacitance level corresponding to the capacitance control code SC[3:0]. In summary, when the capacitance control code SC[3:0]=1000 and the resistance control code SR[3:0]=1000, candidate resistor R1 and candidate capacitor C1 are the selected filtering resistor and filtering capacitor connected in series in the filter. When the capacitance control code SC[3:0] is switched to 0100 and the resistance control code SR[3:0] is switched to 0001, candidate resistor R2 and candidate capacitor C4 are the selected filtering resistor and filtering capacitor connected in series in the filter.

Preferably, in the filter, among all the switch circuits each coupled between the first end of each candidate resistor and the output end of the charge pump, under the control of the resistance control code currently outputted by the circuit parameter regulator, there is at least one switch circuit that changes from an OFF state to an ON state, and there is at least one switch circuit that changes from an ON state to an OFF state, it is determined that the filter switches from the resistance level corresponding to the resistance control code outputted in advance to the resistance level corresponding to the resistance control code outputted currently, so as to increase or decrease the resistance value of the filtering resistor in the filter. In the filter, among all the switch circuits each coupled between the first end of each filtering capacitor and the second end of the corresponding filtering resistor, under the control of the capacitance control code currently outputted by the circuit parameter regulator, there is at least one switch circuit that changes from an OFF state to an ON state, and there is at least one switch circuit that changes from an ON state to an OFF state, it is determined that the filter switches from the capacitance level corresponding to the capacitance control code outputted in advance to the capacitance level corresponding to the capacitance control code outputted currently, so as to increase or decrease the capacitance value of the filtering capacitor in the filter.

In this embodiment, the capacitance value of the reference capacitor is less than the capacitance value of each candidate capacitor. Preferably, the capacitance value of the reference capacitor is less than one-tenth of the capacitance value of each candidate capacitor, and the capacitance value of the reference capacitor is greater than one-twentieth of the capacitance value of each candidate capacitor. In this regard, the capacitance value of the filtering capacitor in the filter is not less than the capacitance value of the reference capacitor, thereby reducing the impact of the capacitance value of the reference capacitor on the loop parameters of the phase-locked loop circuit during the adjustment of the filtering capacitor and the filtering resistor.

Preferably, in the filter, the preset quantity of candidate resistors is arranged sequentially in a predetermined direction, and resistance values of the preset quantity of candidate resistors decrease sequentially in the predetermined direction. The preset quantity of candidate capacitors is arranged sequentially in the predetermined direction, and capacitance values of the preset quantity of candidate capacitors decrease sequentially in the predetermined direction. As shown in FIG. 2, the resistance values of candidate resistors R1, R2, . . . , Rm sequentially decrease from left to right. The capacitance values of candidate capacitors C1, C2, . . . , Cm sequentially increase from left to right. The predetermined direction is the arrangement direction from left to right shown in FIG. 2. In this preferred example, each time the capacitance level is switched, at least one candidate capacitor is selected in the filter as the filtering capacitor. Similarly, each time the resistance level is switched, at least one candidate resistor is selected in the filter as the filtering resistor. As a result, in the case where the gain value of the voltage-controlled oscillator increases, it provides the circuit parameter regulator with the necessary circuit foundation, specifically, the hardware circuitry for executing level switching operations, to reduce the resistance value of the filtering resistor in the filter by a certain factor, thereby controlling the bandwidth ratio to remain within the first preset margin, and increase the capacitance value of the filtering capacitor in the filter by the same certain factor, thereby controlling the damping factor to remain within the second preset margin.

Preferably, in the filter, the preset quantity of candidate capacitors is arranged sequentially in a predetermined direction, and capacitance values of the preset quantity of candidate capacitors increase sequentially in the predetermined direction. As shown in FIG. 2, the capacitance values of candidate capacitors C1, C2, . . . , Cm increase sequentially from left to right. The predetermined direction is the arrangement direction from left to right shown in FIG. 2. When the circuit parameter regulator reduces the frequency division coefficient of the pre-frequency divider and/or increases the frequency of the signal to be processed, the resistance level is maintained, and a direction of switching the capacitance level is opposite to the predetermined direction, to make the capacitance value of the currently selected candidate capacitor be reduced relative to the capacitance value of the last selected candidate capacitor. At this point, other circuit parameters used in the calculation of the bandwidth ratio and the damping factor are relatively fixed. As shown in FIG. 2, direction of switching the capacitance level is from left to right, successively switching candidate resistors with smaller subscripts into the phase-locked loop circuit, achieving a reduction in the resistance value of the filtering resistor in the filter. Each time the capacitance level is switched, at least one candidate capacitor is selected in the filter. This controls the loop parameters generated by the phase-locked loop circuit to be within the preset margin range and reduces the resistance value of the filtering resistor in the filter.

Therefore, the phase-locked loop system configures a control mode capable of selecting relatively small capacitance levels (the resistance level may increase), so that the phase-locked loop circuit established with the selected resistance level, capacitance level, or frequency-division coefficient level of the pre-frequency divider is minimized in area, specifically by selecting a filtering capacitor from the filter that reduces the area occupied by the phase-locked loop circuit.

Preferably, in the filter, the preset quantity of candidate resistors is arranged sequentially in a predetermined direction, and capacitance values of the preset quantity of candidate resistors decrease sequentially in the predetermined direction. As shown in FIG. 2, the resistance values of candidate resistors R1, R2, . . . , Rm decrease from left to right. The predetermined direction is the arrangement direction from left to right shown in FIG. 2. When the gain value of the voltage-controlled oscillator increases, and the resistance level is controlled to change, and a direction of switching the resistance level is the predetermined direction, to make the resistance value of the currently selected candidate resistor be reduced relative to the resistance value of the last selected candidate resistor. At this point, other circuit parameters used in the calculation of the bandwidth ratio and the damping factor are relatively fixed. As shown in FIG. 2, direction of switching the resistance level is from left to right, successively switching candidate resistors with smaller subscripts into the phase-locked loop circuit, achieving a reduction in the resistance value of the filtering resistor in the filter. Each time the resistance level is switched, at least one candidate resistor is selected in the filter. This controls the loop parameters generated by the phase-locked loop circuit to be within the preset margin range and reduces the resistance value of the filtering resistor in the filter.

As one embodiment, the phase-locked loop working system obtains the bandwidth ratio using the following formula (which can be considered as the bandwidth ratio calculated by the circuit parameter regulator):

$$\frac{{ω}_{c}}{{ω}_{i}} = \frac{{R}_{l} * {C}_{l} * \frac{{K}_{d} * {K}_{o}}{N ( {C}_{l} + {C}_{p} )}}{2 * π * fin / Pdiv} = \frac{{R}_{l} * {C}_{l} * \frac{{K}_{d} * {K}_{o}}{N ( {C}_{l} + {C}_{p} )}}{2 * π * \frac{fo}{N}}$$

which may be denoted as the bandwidth ratio calculation formula.

ω_{c} is the loop bandwidth, fin is a frequency of an external input signal to be processed, ωᵢ is the frequency of the signal after frequency division by the loop frequency divider or the frequency of the signal after frequency division by the pre-frequency divider, which is also equal to the frequency of the reference signal. fo is the frequency of the signal inputted into the loop frequency divider, N is the frequency division coefficient of the loop frequency divider, and Pdiv is the frequency division coefficient of the pre-frequency divider. Rₗ is the resistance value of the filtering resistor, Cₗ is the capacitance value of the filtering capacitor, and Cₚ is the capacitance value of the reference capacitor. Kₒ is the gain value of the voltage-controlled oscillator, which is used to indicate a change rate of a frequency of signal outputted by the voltage-controlled oscillator relative to a control voltage of the voltage-controlled oscillator. The change of a power supply voltage required by the phase-locked loop circuit is negatively correlated with the change of Kₒ, and a source of the change of the power supply voltage required by the phase-locked loop circuit comprises a change of a process coefficient of a transistor. K_{d} is a ratio of an output current of the charge pump to a phase of the charge pump. The signal to be processed inputted into the pre-frequency divider originates from a crystal oscillator.

A frequency division manner of the pre-frequency divider is to calculate a ratio of the frequency fin of the signal inputted into the pre-frequency divider to the frequency division coefficient Pdiv of the pre-frequency divider, to obtain a frequency

$$\frac{fin}{Pdiv}$$

of the signal after frequency division, so that the pre-frequency divider uses the frequency division coefficient as a scaling-down factor to perform frequency division operation on the signal. The frequency division coefficient Pdiv of the pre-frequency divider is a positive integer. In the phase-locked loop circuit, it is configured that the frequency of the signal inputted into the loop frequency divider is equal to

$$\frac{fin}{Pdiv} * N .$$

A frequency division manner of the loop frequency divider is to calculate a ratio of the frequency

$$\frac{fin}{Pdiv} * N$$

of the signal inputted into the loop frequency divider to the frequency division coefficient N of the loop frequency divider, and the frequency of the obtained signal is used as the frequency

$$\frac{fin}{Pdiv}$$

of the feedback signal inputted into the phase frequency detector, where the frequency division coefficient N of the loop frequency divider is a positive integer.

In this embodiment, in the bandwidth ratio calculation formula,

$$\frac{{R}_{l} * {C}_{l} * \frac{{K}_{d} * {K}_{o}}{N ( {C}_{l} + {C}_{p} )}}{2 * π * \frac{fo}{N}}$$

is equal to

$$\frac{{R}_{l} * {K}_{d} * {K}_{o}}{2 * π * fo}$$

when the reference capacitance is omitted. Hence, the bandwidth ratio calculation formula is directly expressed as

$$\frac{{ω}_{c}}{{ω}_{i}} = \frac{{R}_{l} * {K}_{d} * {K}_{o}}{2 * π * fo}$$

where

$$\frac{{ω}_{c}}{{ω}_{i}}$$

is the bandwidth ratio.

Based on the above embodiments, the phase-locked loop working system obtains the damping coefficient using the following formula (which can be considered as the damping coefficient calculated by the circuit parameter regulator).

Specifically, the phase-locked loop working system calculates the damping coefficient using the following formula when the reference capacitance is omitted:

$$\begin{matrix}ζ = \frac{{R}_{l} * {C}_{l}}{2} * \sqrt{\frac{{K}_{d} * {K}_{o}}{N ( {C}_{P} * {C}_{l} )}} = \frac{{R}_{l}}{2} * \sqrt{\frac{{K}_{d} * {K}_{o} * {C}_{l}}{N}} \\ = \frac{{R}_{l}}{2} * \sqrt{\frac{{K}_{d} * {K}_{o} * {C}_{l} * fin / Pdiv}{N * fin / Pdiv}} = \frac{{R}_{l}}{2} * \sqrt{\frac{{K}_{d} * {K}_{o} * {C}_{l} * fin}{fo * Pdiv}}\end{matrix}$$

Hence, in this embodiment, the damping coefficient calculation formula is expressed as

$$ζ = \frac{{R}_{l}}{2} * \sqrt{\frac{{K}_{d} * {K}_{o} * {C}_{l} * fin}{fo * Pdiv}}$$

where ζ is the damping factor.

When the capacitance value of the reference capacitor is less than one-tenth of the capacitance value of the filtering capacitor, the reference capacitor may be omitted in the bandwidth ratio calculation formula and the damping factor calculation formula.

In this embodiment, when the circuit parameter regulator controls the loop parameters generated by the phase-locked loop circuit to be within the preset margin range by changing the filtering resistor and the filtering capacitor in the filter, it includes adjusting the filtering resistor in the filter according to the bandwidth ratio calculation formula and adjusting the filtering capacitor in the filter according to the damping factor calculation formula.

Specifically, adjusting the filtering resistor in the filter according to the bandwidth ratio calculation formula includes: in a case where the circuit parameter regulator maintains fo and K_{d}, and Kₒ increases, the circuit parameter regulator reduces the resistance value Rₗ of the filtering resistor, to enable the bandwidth ratio to be within the first preset margin range; in a case where the circuit parameter regulator maintains fo and K_{d}, and Kₒ decreases, the circuit parameter regulator increases the resistance value Rₗ of the filtering resistor, to enable the bandwidth ratio to be within the first preset margin range.

Specifically, adjusting the filtering capacitor in the filter according to the damping factor calculation formula includes: in a case where the circuit parameter regulator maintains fo, K_{d}, fin and Pdiv, and Kₒ increases and the resistance value Rₗ of the filtering resistor decreases, the circuit parameter regulator increases the capacitance value Cₗ of the filtering capacitor, to enable the damping factor to be within the second preset margin range and the bandwidth ratio to be within the first preset margin range, where the multiplication factor by which the capacitance value Cₗ is increased is equal to the multiplication factor by which the resistance value Rₗ is reduced, and is also equal to the multiplication factor by which Kₒ increases. In a case where the circuit parameter regulator maintains fo, K_{d},fin and Pdiv, Kₒ decreases and the resistance value Rₗ of the filtering resistor increases, the circuit parameter regulator decreases the capacitance value Cₗ of the filtering capacitor, to enable the damping factor to be within the second preset margin range and the bandwidth ratio to be within the first preset margin range, where the multiplication factor by which the capacitance value Cₗ is reduced is equal to the multiplication factor by which the resistance value Rₗ is increased, and is also equal to the multiplication factor by which Kₒ decreases.

It should be noted that the first preset margin range is preferably less than 0.1. The second preset margin range is preferably less than or equal to 0.707 and greater than or equal to 0.5. The damping factor needs to be set around 0.707. An excessively large damping factor may cause the phase-locking operation performed by the phase-locked loop to be slow, while an excessively small damping factor may cause slow decay of the phase-locked loop oscillation or even a failure to achieve lock. A large damping factor is tolerable, but a small damping factor constitutes a certain risk. Thus, the damping factor is usually not less than 0.5.

Furthermore, in this embodiment, when the circuit parameter regulator controls the loop parameters generated by the phase-locked loop circuit to be within the preset margin range and adjusts the capacitance value of the filtering capacitor in the filter by adjusting the frequency division coefficient of the pre-frequency divider or the frequency of the signal to be processed inputted into the pre-frequency dividers, it includes adjusting the capacitance value of the filtering capacitor in the filter by adjusting the frequency division coefficient of the pre-frequency divider and/or the frequency of the signal to be processed inputted into the pre-frequency divider, based on the damping factor calculation formula. This achieves maintaining a certain frequency accuracy and outputting reasonable frequency division coefficient values.

As one embodiment, the circuit parameter regulator adjusting the capacitance value of the filtering capacitor in the filter by adjusting the frequency division coefficient of the pre-frequency divider and/or the frequency of the signal to be processed inputted into the pre-frequency divider based on the damping factor calculation formula, includes: in a case where the circuit parameter regulator maintains the bandwidth ratio, Rₗ, K_{d}, fin and Kₒ, and reduces Pdiv, reducing, by the circuit parameter regulator, the capacitance value Cₗ of the filtering capacitor, to enable the damping factor to be within the second preset margin range. In this regard, the area occupied by the filtering capacitor in the filter is reduced. Pdiv is reduced by the same multiplication factor as Cₗ. Pdiv is reduced by the same multiplication factor as the frequency division coefficient of the loop frequency divider, so as to maintain the frequency fo of the signal inputted into the loop frequency divider.

As one embodiment, the circuit parameter regulator adjusting the capacitance value of the filtering capacitor in the filter by adjusting the frequency division coefficient of the pre-frequency divider and/or the frequency of the signal to be processed inputted into the pre-frequency divider based on the damping factor calculation formula, further includes: in a case where the circuit parameter regulator maintains the bandwidth ratio, fo, Rₗ, K_{d}, Pdiv and Kₒ, and fin is increased, reducing, by the circuit parameter regulator, the capacitance value Cₗ of the filtering capacitor, so as to enable the damping factor to be within the second preset margin range. In this regard, the area occupied by the filtering capacitor in the filter is reduced. The multiplication factor by which fin is increased is equal to the multiplication factor by which Cₗ is reduced. The multiplication factor by which fin is increased is equal to the multiplication factor by which the frequency division coefficient of the loop frequency divider is reduced, so as to maintain the frequency fo of the signal inputted into the loop frequency divider.

As one embodiment, the circuit parameter regulator adjusting the capacitance value of the filtering capacitor in the filter by adjusting the frequency division coefficient of the pre-frequency divider and/or the frequency of the signal to be processed inputted into the pre-frequency divider, based on the damping factor calculation formula, further includes: in a case where the circuit parameter regulator maintains fo, K_{d} and fin, and Kₒ increases, reducing, by the circuit parameter regulator, the resistance value Ry of the filtering resistor, so as to enable the bandwidth ratio to be within the first preset margin range. In the same bandwidth ratio calculation formula, the multiplication factor by which the resistance value Rₗ is reduced is equal to the multiplication factor by which Kₒ increases. Furthermore, the circuit parameter regulator reduces Pdiv, and the circuit parameter regulator causes the damping factor to be within the second preset margin range without increasing the capacitance value Cₗ of the filtering capacitor. In the same damping factor calculation formula, after the resistance value Rₗ is reduced, a multiplication factor by which a value inside the square root in the damping factor calculation formula is increased needs to be configured as the square of the multiplication factor by which the resistance value Rₗ is reduced, which is also equal to the square of the multiplication factor by which Kₒ increases. When maintaining the loop parameters generated by the phase-locked loop circuit within the preset margin range, if the capacitance value Cₗ of the filtering capacitor is reduced, it actually decreases the value in the square root in the damping factor calculation formula. However, controlling Pdiv to decrease actually increases the value in the square root in the damping factor calculation formula. Therefore, the ratio of the multiplication factor by which Pdiv is reduced to the multiplication factor by which the capacitance value Cₗ of the filtering capacitor is reduced is configured to be equal to the multiplication factor by which Kₒ increases. The value in the square root in the damping factor calculation formula shows an overall increasing trend, thereby configuring the multiplication factor by which the value in the square root in the damping factor calculation formula is increased to be the square of the multiplication factor by which Kₒ increases, thereby forming a small-area phase-locked loop circuit parameter configuration.

As one embodiment, the circuit parameter regulator adjusting the capacitance value of the filtering capacitor in the filter by adjusting the frequency division coefficient of the pre-frequency divider and/or the frequency of the signal to be processed inputted into the pre-frequency divider, based on the damping factor calculation formula, further includes: in a case where the circuit parameter regulator maintains fo, K_{d}, and fin, and Kₒ decreases, increasing, by the circuit parameter regulator, the resistance value Rₗ of the filtering resistor, so as to enable the bandwidth ratio to within the first preset margin range. In the same bandwidth ratio calculation formula, the multiplication factor by which the resistance value Rₗ is increased is equal to the multiplication factor by which Kₒ decreases. Furthermore, the circuit parameter regulator reduces Pdiv, and the circuit parameter regulator causes the damping factor to be within the second preset margin range while decreasing the capacitance value Cₗ of the filtering capacitor. In the same damping factor calculation formula, after the resistance value Rₗ is increased, the multiplication factor by which the value inside the square root in the damping factor calculation formula is reduced needs to be configured as the square of the multiplication factor by which the resistance value Rₗ is increased, which is also equal to the square of the multiplication factor by which Kₒ decreases. When maintaining the loop parameters generated by the phase-locked loop circuit within the preset margin range, if the capacitance value Cₗ of the filtering capacitor is reduced, it actually decreases the value inside the square root in the damping factor calculation formula. While controlling Pdiv to decrease actually increases the value in the square root in the damping factor calculation formula. Therefore, the ratio between the multiplication factor by which the capacitance value Cₗ of the filtering capacitor is reduced and the multiplication factor by which Pdiv is reduced is configured to be equal to the multiplication factor by which Kₒ decreases. The value in the square root in the damping factor calculation formula shows an overall decreasing trend, thereby configuring the multiplication factor by which the value in the square root in the damping factor calculation formula is reduced to be the square of the multiplication factor by which Kₒ decreases. This causes the multiplication factor by which the capacitance value Cₗ of the filtering capacitor is reduced to be greater than the multiplication factor by which it is reduced when Kₒ increases, thereby forming a small-area phase-locked loop circuit parameter configuration.

As one embodiment, the circuit parameter regulator adjusting the capacitance value of the filtering capacitor in the filter by adjusting the frequency division coefficient of the pre-frequency divider and/or the frequency of the signal to be processed inputted into the pre-frequency divider, based on the damping factor calculation formula, further includes: in a case where the circuit parameter regulator maintains fo, K_{d}, and Pdiv, and Kₒ increases, reducing, by the circuit parameter regulator, the resistance value Rₗ of the filtering resistor, so as to enable the bandwidth ratio to within the first preset margin range. In the same bandwidth ratio calculation formula, the multiplication factor by which the resistance value Rₗ is reduced is equal to the multiplication factor by which Kₒ increases. After the resistance value Rₗ is reduced, the multiplication factor by which the value inside the square root in the damping factor calculation formula is increased needs to be configured as the square of the multiplication factor by which the resistance value Rₗ is reduced, which is also equal to the square of the multiplication factor by which Kₒ increases. Hence, when maintaining the loop parameters generated by the phase-locked loop circuit within the preset margin range, if the capacitance value Cₗ of the filtering capacitor is reduced (which actually decreases the value in the square root in the damping factor calculation formula) while controlling fin to increase (which actually increases the value in the square root in the damping factor calculation formula), the ratio between the multiplication factor by which fin is increased and the multiplication factor by which the capacitance value Cₗ of the filtering capacitor is reduced is configured to be equal to the multiplication factor by which Kₒ increases, thereby configuring the multiplication factor by which the value in the square root in the damping factor calculation formula is increased to be the square of the multiplication factor by which Kₒ increases. The multiplication factor by which fin is increased is greater than the multiplication factor by which the capacitance value Cₗ of the filtering capacitor is reduced. This ensures that the value in the square root in the damping factor calculation formula still increases despite the reduction in the capacitance value Cₗ of the filtering capacitor, merely suppressing the multiplication factor of increasing to balance the phase-locked loop circuit area, thereby forming a small-area phase-locked loop circuit parameter configuration.

As one embodiment, the circuit parameter regulator adjusting the capacitance value of the filtering capacitor in the filter by adjusting the frequency division coefficient of the pre-frequency divider and/or the frequency of the signal to be processed inputted into the pre-frequency divider, based on the damping factor calculation formula, further includes: in a case where the circuit parameter regulator maintains fo, K_{d}, and Pdiv, and Kₒ decreases, increasing, by the circuit parameter regulator, the resistance value Rₗ of the filtering resistor, so as to enable the bandwidth ratio to within the first preset margin range. In the same bandwidth ratio calculation formula, the multiplication factor by which the resistance value Rₗ is increased is equal to the multiplication factor by which Kₒ decreases. After the resistance value Ru is increased, the multiplication factor by which the value in the square root in the damping factor calculation formula is reduced needs to be configured as the square of the multiplication factor by which the resistance value Rₗ is increased, which is also equal to the square of the multiplication factor by which Kₒ decreases. When maintaining the loop parameters generated by the phase-locked loop circuit within the preset margin range, if the capacitance value Cₗ of the filtering capacitor is reduced, it actually decreases the value in the square root in the damping factor calculation formula; while increasing fin, it actually increases the value in the square root in the damping factor calculation formula. Hence, the ratio between the multiplication factor by which the capacitance value Cₗ of the filtering capacitor is reduced and the multiplication factor by which fin is increased is configured to be equal to the multiplication factor by which Kₒ decreases, and the multiplication factor by which fin is increased is less than the multiplication factor by which the capacitance value Cₗ of the filtering capacitor is reduced, thereby configuring the multiplication factor by which the value inside the square root in the damping factor calculation formula is reduced to be the square of the multiplication factor by which Kₒ decreases. Therefore, even if fin increases, it does not prevent the value ins the square root in the damping factor calculation formula from decreasing. This merely suppressing the multiplication factor of decreasing to balance reducing the phase-locked loop circuit area and the stable operating state, thus forming a small-area phase-locked loop circuit parameter configuration.

According to the above formulas, the corresponding technical solutions adjust the filtering resistor in the filter according to the calculation formula of the bandwidth ratio and adjust the capacitance value of the filtering capacitor and the resistance value of the filtering resistor in the filter according to the calculation formula of the damping factor. Based on the damping factor calculation formula, the corresponding technical solutions adjust the capacitance value of the filtering capacitor in the filter by adjusting a frequency-division coefficient of the pre-frequency divider and/or a frequency of the signal to be processed inputted into the pre-frequency divider, to maintaining a certain frequency accuracy and outputting reasonable circuit parameters or loop parameters. Even if partial circuit parameters are fixed, according to the formulas of calculating the bandwidth ratio and the damping factor, the circuit parameters of the phase-locked loop circuit can be flexibly adjusted to ensure stable operation of the phase-locked loop circuit.

It should be noted that the above embodiments are merely used to illustrate the technical solutions of this application, but shall not be construed as limiting this application. As can be appreciated by a person skilled in the art, although this application has been described in detail with reference to the foregoing embodiments, any modifications of the embodiments in this application or equivalent replacements of the technical features, may still be made by the person skilled in the art. These modifications or replacements, made without departing from the spirit of this application, shall be encompassed within the scope of claimed technical solutions of this application.

What is claimed is:

1. A phase-locked loop working system, comprising: a pre-frequency divider, a phase frequency detector, a charge pump, a filter, a voltage-controlled oscillator, a loop frequency divider and a circuit parameter regulator; wherein
the phase frequency detector, the charge pump, the filter, the voltage-controlled oscillator and the loop frequency divider are sequentially coupled end to end to form a phase-locked loop circuit;
the circuit parameter regulator is coupled to the phase-locked loop circuit and is used to adjust a filtering resistor and a filter capacitor in the filter, to control a loop parameter generated by the phase-locked loop circuit to be within a preset margin range; and
the circuit parameter regulator is coupled to the phase-locked loop circuit and is further used to adjust at least one of a frequency division coefficient of the pre-frequency divider or a frequency of the signal to be processed inputted into the pre-frequency divider, to control the loop parameter generated by the phase-locked loop circuit to be within the preset margin range, and to reduce a capacitance value of the filtering capacitor in the filter.

2. The phase-locked loop working system according to claim 1, wherein
the circuit parameter regulator is used to:
reduce a resistance value of the filtering resistor in the filter when a gain value of the voltage-controlled oscillator increases, to control a bandwidth ratio to be within a first preset margin range; and
increase the capacitance value of the filtering capacitor in the filter, to control a damping coefficient to be within a second preset margin range;
the gain value of the voltage-controlled oscillator increases by a same multiplication factor as the capacitance value of the filtering capacitor, so that the capacitance value of the filtering capacitor in the filter is not adjusted to increase by a square factor when used in the calculation of the damping coefficient;
the circuit parameter regulator is used to:
increase the resistance value of the filtering resistor in the filter when the gain value of the voltage-controlled oscillator decreases, to control the bandwidth ratio to be within the first preset margin range; and
decrease the capacitance value of the filtering capacitor in the filter, to control the damping coefficient to be within the second preset margin range; wherein the gain value of the voltage-controlled oscillator decreases by a same multiplication factor as the capacitance value of the filtering capacitor;
the loop parameter generated by the phase-locked loop circuit comprises the bandwidth ratio and the damping coefficient; the preset margin range comprises the first preset margin range and the second preset margin range, and the first preset margin range is different from the second preset margin range; and
when the bandwidth ratio is within the first preset margin range and the damping coefficient is within the second preset margin range, the loop parameter generated by the phase-locked loop circuit is within the preset margin range.

3. The phase-locked loop working system according to claim 2, wherein
the circuit parameter regulator is used to:
after determining that the gain value of the voltage-controlled oscillator increases, the resistance value of the filtering resistor in the filter is reduced, the capacitance value of the filtering capacitor in the filter is increased, and the calculated loop parameter of the phase-locked loop is within the preset margin range, when the frequency of the signal to be processed remains unchanged and the frequency division coefficient of the pre-frequency divider is reduced, reduce the capacitance value of the filtering capacitor in the filter, to control the damping coefficient to be within the second preset margin range, wherein the frequency division coefficient of the pre-frequency divider decreases by a same multiplication factor as the capacitance value of the filtering capacitor; and
the circuit parameter regulator is further used to:
after determining that the gain value of the voltage-controlled oscillator increases, the resistance value of the filtering resistor in the filter is reduced, the capacitance value of the filtering capacitor in the filter is increased, and the calculated loop parameter of the phase-locked loop is within the preset margin range, when the frequency of the signal to be processed is increases and the frequency division coefficient of the pre-frequency divider remains unchanged, reduce the capacitance value of the filtering capacitor in the filter, to control the damping coefficient to be within the second preset margin range, wherein a multiplication factor by which the frequency of the signal to be processed is increased is equal to a multiplication factor by which the capacitance value of the filtering capacitor is reduced.

4. The phase-locked loop working system according to claim 3, wherein the circuit parameter regulator is used to:
after determining that the gain value of the voltage-controlled oscillator increases, the resistance value of the filtering resistor in the filter is reduced, the capacitance value of the filter capacitor inside the filter is increased, and the calculated loop parameter of the phase-locked loop is within the preset margin range, when the frequency of the signal to be processed increases and the frequency division coefficient of the pre-frequency divider is reduced, reduce the capacitance value of the filtering capacitor in the filter, to control the damping coefficient to be within the second preset margin range; wherein a product of a multiplication factor by which the frequency division coefficient of the pre-frequency divider is reduced and a multiplication factor by which the frequency of the signal to be processed increases is equal to a multiplication factor by which the capacitance value of the filtering capacitor is reduced.

5. The phase-locked loop working system according to claim 1, wherein
the circuit parameter regulator is used to:
reduce the resistance value of the filtering resistor in the filter when the gain value of the voltage-controlled oscillator increases, to control a bandwidth ratio to be within a first preset margin range; wherein a multiplication factor by which the resistance value of the filtering resistor is decreased is equal to a multiplication factor by which the gain value of the voltage-controlled oscillator increases; and
reduce the frequency division coefficient of the pre-frequency divider and reduce the capacitance value of the filtering capacitor in the filter, to control a damping coefficient to be within a second preset margin range; wherein a ratio of a multiplication factor by which the frequency division coefficient of the pre-frequency divider is reduced to a multiplication factor by which the capacitance value of the filtering capacitor is reduced is equal to a multiplication factor by which the gain value of the voltage-controlled oscillator increases, and the multiplication factor by which the frequency division coefficient of the pre-frequency divider is reduced is greater than the multiplication factor by which the capacitance value of the filtering capacitor is reduced;
the circuit parameter regulator is further used to:
increase the resistance value of the filtering resistor in the filter when the gain value of the voltage-controlled oscillator decreases, to control the bandwidth ratio to be within the first preset margin range, wherein a multiplication factor by which the resistance value of the filtering resistor is increased is equal to a multiplication factor by which the gain value of the voltage-controlled oscillator decreases; and
reduce the frequency division coefficient of the pre-frequency divider, and reduce the capacitance value of the filtering capacitor in the filter, to control the damping coefficient to be within the second preset margin range, wherein a ratio of the multiplication factor by which the capacitance value of the filtering capacitor is reduced to the multiplication factor by which the frequency division coefficient of the pre-frequency divider is reduced is equal to the multiplication factor by which the gain value of the voltage-controlled oscillator decreases, and the multiplication factor by which the frequency division coefficient of the pre-frequency divider is reduced is less than the multiplication factor by which the capacitance value of the filtering capacitor is reduced;
the loop parameter generated by the phase-locked loop circuit comprises the bandwidth ratio and the damping coefficient; the preset margin range comprises the first preset margin range and the second preset margin range, and the first preset margin range is different from the second preset margin range; and
when the bandwidth ratio is within the first preset margin range and the damping coefficient is within the second preset margin range, the loop parameter generated by the phase-locked loop circuit is within the preset margin range.

6. The phase-locked loop working system according to claim 1, wherein
the circuit parameter regulator is used to:
reduce the resistance value of the filtering resistor in the filter when the gain value of the voltage-controlled oscillator increases, to control a bandwidth ratio to be within a first preset margin range, wherein a multiplication factor by which the resistance value of the filtering resistor is decreased is equal to a multiplication factor by which the gain value of the voltage-controlled oscillator increases; and
increase the frequency of the signal to be processed, and reduce the capacitance value of the filtering capacitor in the filter, to control a damping coefficient to be within a second preset margin range, wherein a ratio of a multiplication factor by which the frequency of the signal to be processed is increased to a multiplication factor by which the capacitance value of the filtering capacitor is reduced is equal to a multiplication factor by which the gain value of the voltage-controlled oscillator increases, and the multiplication factor by which the frequency of the signal to be processed is increased is greater than the multiplication factor by which the capacitance value of the filtering capacitor is reduced;
the circuit parameter regulator is further used to:
increase the resistance value of the filtering resistor in the filter when the gain value of the voltage-controlled oscillator decreases, to control the bandwidth ratio to be within the first preset margin range, wherein a multiplication factor by which the resistance value of the filtering resistor is increased is equal to a multiplication factor by which the gain value of the voltage-controlled oscillator decreases; and
increase the frequency of the signal to be processed, and reduce the capacitance value of the filtering capacitor in the filter, to control the damping coefficient to be within the second preset margin range, wherein
a ratio of the multiplication factor by which the capacitance value of the filtering capacitor is reduced to the multiplication factor by which the frequency of the signal to be processed is increased is equal to the multiplication factor by which the gain value of the voltage-controlled oscillator decreases, and the multiplication factor by which the frequency of the signal to be processed is increased is less than the multiplication factor by which the capacitance value of the filtering capacitor is reduced;
the loop parameter generated by the phase-locked loop circuit comprises the bandwidth ratio and the damping coefficient; the preset margin range comprises the first preset margin range and the second preset margin range, and the first preset margin range is different from the second preset margin range; and
when the bandwidth ratio is within the first preset margin range and the damping coefficient is within the second preset margin range, the loop parameter generated by the phase-locked loop circuit is within the preset margin range.

7. The phase-locked loop working system according to claim 3, wherein a frequency division manner of the pre-frequency divider is to calculate a ratio of the frequency of the signal inputted into the pre-frequency divider to the frequency division coefficient of the pre-frequency divider, to obtain a frequency of the signal after frequency division by the pre-frequency divider, so that the pre-frequency divider uses the frequency division coefficient as a scaling-down factor to perform frequency division operation on the signal; wherein the frequency division coefficient of the pre-frequency divider is a positive integer, which is determined by a counting modulus value of a counter set in the pre-frequency divider, and is adjustable in response to a corresponding trigger signal from the circuit parameter regulator; and
a frequency division manner of the loop frequency divider is to calculate a ratio of the frequency of the signal inputted into the loop frequency divider to a frequency division coefficient of the loop frequency divider, and the frequency of the signal after frequency division by the loop frequency divider is equal to the frequency of the signal after frequency division by the pre-frequency divider; wherein, the frequency division coefficient of the loop frequency divider is a positive integer, which is determined by the counting modulus value of the counter set in the loop frequency divider, and is adjustable in response to the trigger signal from the circuit parameter regulator.

8. The phase-locked loop working system according to claim 7, wherein the filter is provided with a preset quantity of resistance levels and a preset quantity of capacitance levels, each resistance level has a matching capacitance level, and corresponding filtering resistor and filtering capacitor are connected in series;
the circuit parameter regulator is used to output a control code to the filter;
the circuit parameter regulator is coupled to the filter and is used to switch the resistance level to change the resistance value of the filtering resistor in the filter and switch the capacitance level to change the capacitance value of the filtering capacitor in the filter when receiving the control code; and
the preset quantity is greater than or equal to 2.

9. The phase-locked loop working system according to claim 8, wherein the control code comprises a capacitance control code corresponding to the capacitance value and a resistance control code corresponding to the resistance value;
the filter comprises a preset quantity of candidate capacitors, a preset quantity of candidate resistors, a reference capacitor and twice the preset quantity of switch circuits;
a first end of each candidate resistor is coupled to an output end of the charge pump through one switch circuit, a second end of each candidate resistor is coupled to a first end of one corresponding candidate capacitor through one switch circuit, and a second end of each candidate capacitor is coupled to the ground, wherein a second end of each candidate resistor is coupled together; a first end of the reference capacitor is coupled to the output end of the charge pump, a second end of the reference capacitor is coupled to the ground, and the first end of the reference capacitor is further coupled to an input end of the voltage-controlled oscillator;
the resistance control code corresponding to the resistance value outputted by the circuit parameter adjuster is used to control the switch circuit coupled between the first end of the candidate resistor and the output end of the charge pump to be in an ON or OFF state, and when the switch circuit coupled between the first end of the candidate resistor and the output end of the charge pump is in an ON state, it indicates that the candidate resistor connected to the switch circuit in the ON state is selected, the selected candidate resistor is determined as the filtering resistor in the filter, and it is determined that the filter switches to the resistance level corresponding to the resistance control code;
the capacitance control code corresponding to the capacitance value outputted by the circuit parameter adjuster is used to control the switch circuit coupled between the first end of the candidate capacitor and the second end of the candidate resistor to be in ON or OFF state; when the switch circuit coupled between the first end of the candidate capacitor and the second end of the candidate resistor is in the ON state, it indicates that the candidate capacitor connected to the switch circuit in the ON state is selected, and the selected candidate capacitor is determined as the filtering capacitor in the filter, and it is determined that the filter switches to the capacitance level corresponding to the capacitance control code.

10. The phase-locked loop working system according to claim 9, wherein in the filter, among all the switch circuits each coupled between the first end of each candidate resistor and the output end of the charge pump, under the control of the resistance control code currently outputted by the circuit parameter regulator, there is at least one switch circuit that changes from an OFF state to an ON state, and there is at least one switch circuit that changes from an ON state to an OFF state, it is determined that the filter switches from the resistance level corresponding to the resistance control code outputted in advance to the resistance level corresponding to the resistance control code outputted currently, so as to increase or decrease the resistance value of the filtering resistor in the filter;
in the filter, among all the switch circuits each coupled between the first end of each filtering capacitor and the second end of the corresponding filtering resistor, under the control of the capacitance control code currently outputted by the circuit parameter regulator, there is at least one switch circuit that changes from an OFF state to an ON state, and there is at least one switch circuit that changes from an ON state to an OFF state, it is determined that the filter switches from the capacitance level corresponding to the capacitance control code outputted in advance to the capacitance level corresponding to the capacitance control code outputted currently, so as to increase or decrease the capacitance value of the filtering capacitor in the filter; and
the capacitance value of the reference capacitor is less than the capacitance value of the candidate capacitor.

11. The phase-locked loop working system according to claim 10, wherein, in the filter, the preset quantity of candidate resistors are arranged sequentially in a predetermined direction, and resistance values of the preset quantity of candidate resistors decrease sequentially in the predetermined direction; the preset quantity of candidate capacitors are arranged sequentially in the predetermined direction, and capacitance values of the preset quantity of candidate capacitors decrease sequentially in the predetermined direction; and
each time the capacitance level is switched, at least one candidate capacitor is selected in the filter as the filtering capacitor; and each time the resistance level is switched, at least one candidate resistor is selected in the filter as the filtering resistor.

12. The phase-locked loop working system according to claim 10, wherein, in the filter, the preset quantity of candidate capacitors are arranged sequentially in a predetermined direction, and capacitance values of the preset quantity of candidate capacitors increase sequentially in the predetermined direction;
when the circuit parameter regulator performs at least one of following: reducing the frequency division coefficient of the pre-frequency divider or increasing the frequency of the signal to be processed, a direction of switching the capacitance level being opposite to the predetermined direction, to make the capacitance value of the currently selected capacitor being reduced relative to the capacitance value of the last selected capacitor, thereby reducing the capacitance value of the filtering capacitor in the filter; wherein each time the capacitance level is switched, at least one candidate capacitor is selected in the filter.

13. The phase-locked loop working system according to claim 7, wherein the phase-locked loop working system calculates the bandwidth ratio using following formula:
$$\frac{{ω}_{c}}{{ω}_{i}} = \frac{{R}_{l} * {C}_{l} * \frac{{K}_{d} * {K}_{o}}{N ( {C}_{l} + {C}_{p} )}}{2 * π * fin / Pdiv} = \frac{{R}_{l} * {C}_{l} * \frac{{K}_{d} * {K}_{o}}{N ( {C}_{l} + {C}_{p} )}}{2 * π * \frac{fo}{N}}$$
wherein, ω_{c} is a loop bandwidth, fin is a frequency of an external input signal to be processed, ωᵢ is the frequency of the signal after frequency division by the loop frequency divider or the frequency of the signal after frequency division by the pre-frequency divider, fo is the frequency of the signal inputted into the loop frequency divider, N is the frequency division coefficient of the loop frequency divider, and Pdiv is the frequency division coefficient of the pre-frequency divider;
Rₗ is the resistance value of the filtering resistor, Cₗ is the capacitance value of the filtering capacitor, and Cₚ is the capacitance value of the reference capacitor;
Kₒ is the gain value of the voltage-controlled oscillator, which is used to indicate a change rate of a frequency of signal outputted by the voltage-controlled oscillator relative to a control voltage of the voltage-controlled oscillator; the change of a power supply voltage required by the phase-locked loop circuit is negatively correlated with the change of Kₒ, and a source of the change of the power supply voltage required by the phase-locked loop circuit comprises a change of a process coefficient of a transistor; and
K_{d} is a ratio of an output current of the charge pump to a phase of the charge pump.

14. The phase-locked loop working system according to claim 13, wherein in the formula of calculating the bandwidth ratio,
$$\frac{{R}_{l} * {C}_{l} * \frac{{K}_{d} * {K}_{o}}{N ( {C}_{l} + {C}_{p} )}}{2 * π * \frac{fo}{N}}$$
is equal to
$$\frac{{R}_{l} * {K}_{d} * {K}_{o}}{2 * π * fo}$$
when the reference capacitance is omitted.

15. The phase-locked loop working system according to claim 14, wherein the phase-locked loop working system uses following formula to calculate the damping coefficient:
$$ζ = \frac{{R}_{l}}{2} * \sqrt{\frac{{K}_{d} * {K}_{o} * {C}_{l} * fin}{fo * Pdiv}}$$
